(19) United States
(12) Patent Application Publication
(10) Pub. No.: US 2002/0136165 A1
(43) Pub. Date: Sep. 26, 2002

(54) Cable modem with autonomous diagnostic function

(76) Inventors: Roger Ady, Chicago, IL (US); Michael Patrick, Assonet, MA (US)

Correspondence Address: MOTOROLA, INC., 1303 EAST ALGONQUIN ROAD, IL01/3RD, SCHAUMBURG, IL, 60196

(21) Appl. No.: 09/816,917

(22) Filed: Mar. 23, 2001

(51) Int. Cl. G01R 31/08; G06F 11/00; G08C 15/00

(52) U.S. Cl. 370/241; 375/224

(57) ABSTRACT

A self testable communications device (102) such as a cable modem, a system (100) of remotely distributed such devices (102) and the method (140) of testing. One or more cable modems (102) are connected to a distribution hub (110). Each cable modem (102) includes a connection test initiator, such as a button (130) on the cable modem (102), on a web page or, on a computer (104) desk top which is accessible from the particular cable modem (102). When a test (140) is initiated by pressing or selecting the button (130), the system (100) initiates diagnostics (140) to check the connection of the cable modem (102) to the distribution hub (110). After the test (140) is complete, the cable modem user is provided with an automatic response indicating connection test

### BACKGROUND OF THE INVENTION

1. Field of the Invention

The present invention is related to servicing remotely connected units and, more particularly, to diagnosing broadband connection problems, especially between a cable modem and the network to which it is connected.

2. Background Description

Broadband Internet communications systems such as digital subscriber line (DSL) and cable modems are well known. Standards have been promulgated by industry participants to insure services and hardware compatibility. Cable modem standards are set forth in the Data-Over-Cable Service Interface Specifications (DOCSIS), e.g. Radio Frequency Interface (RFI) Specifications. These Specifications are continuously being refined, revised and updated.

In the modem communications business, as in many businesses today, service and support are key differentiating factors for customers. This is particularly true with those users that may shy away from purchasing the latest technology absent knowledge that they will have easy access to service support for installation and maintenance of their system. In particular, cable service providers, generally, have a poor reputation for service and support. Even though new products and services may be available from cable companies, customers may be wary of signing up for new services when support is uncertain. Further, cable customers are ill-equipped to perform diagnostics on any of the products and services provided by the cable companies. Consequently, service can be the differentiating feature between service providers.

Typically, someone having problems with a high-tech device calls a customer help number, contacting what is typically referred to as the “help desk.” The customer may have to navigate through a voice response system to get to a customer service representative at the help desk. Once in contact with a help desk, the customer support representative may ask the customer a number of intimidating complex technical questions. The customer service representative may pass the customer off to the modem manufacturer to debug what the customer service representative says is a modem problem. Often the supporting entity, whether the cable company or the modem manufacturer, must access the modem to run diagnostic tests in order to identify possible causes of problems. Even after running a suite of diagnostic tests on customer hardware, a follow-up call may be required.

Often, what the customer perceives as a problem may not be a real problem at all, but derive from some external event. Help desks can get inundated during system-wide problems (i.e., router issues, weather, major Internet events) and provide poor customer service. It is believed that cable companies could expand their cable modem subscriber base, significantly, if they can overcome their reputation for poor service and support.

However, even if these service problems are addressed, the key to changing customer perception lies in creating a support plan that is radically different from status quo. For example, the plan must not only be easy and convenient to use, but it should demonstrate that cable companies have confidence in their product. Further, the customer support plan must put the customer in control, or, at least, make the customer feel in control. In addition, providing easy and convenient service and support is especially important to avoid scaring away vast numbers of potential new users. Most of these potential new users are technical novices but who, nonetheless, have been seduced by the buzz surrounding newer technology, such as broadband Internet services.

Customers loathe these long phone calls that may be peppered with intimidating technical questions. Since, in this situation, the customer feels very much out of control, he or she is likely to get very frustrated very quickly.

Staffing a help desk and managing customer relations place a heavy burden on cable modem service providers. Weather-related outages, headend equipment failures, or unexpected high-traffic Internet events, such as for example, the recent Victoria's Secret on-line fashion shows, can wreck havoc on a service organization, as well as increasing customer frustration. Typically, the service provider must balance expected call volume against staffing capabilities. Regardless of whether the problem is real or imagined, due to a hardware failure or, simply the result of heavy web traffic, multiple calls or lengthy calls that can result when diagnostic work is being performed can be expected if a typical service and support model is followed.

Accordingly, there is a need for improvement in diagnosing problems with remotely connected customer appliances and, especially, diagnosing cable modem service subscriber problems.

### BRIEF DESCRIPTION OF THE DRAWINGS

The foregoing and other objects, aspects and advantages will be better understood from the following detailed preferred embodiment description with reference to the drawings, in which:

FIG. 1 shows an example of a self-testable system, including a remotely connectable device, such as a cable modem, testable using self-diagnosis according to the preferred embodiment of the invention;

FIG. 2A-2B shows a flow diagram of an automatic self diagnostic method according to the preferred embodiment of the present invention;

FIG. 3 shows an example of a cable modem service call status window;

FIG. 4 shows an example of a window for directing the customer to contact the service provider during a complete cable modem communications failure;

FIGS. 5A-B shows an example of a cable modem with a callback button prominently located according to a first preferred embodiment;

FIG. 6 shows an illustration of a website callback button in a second preferred embodiment wherein the customer selects the website, and clicks on the website button to initiate a callback from the website.

### DETAILED DESCRIPTION OF PREFERRED EMBODIMENTS

Generally, the present invention is a paradigm for obtaining servicing from a service supplier that shifts control from the service center of the supplier to the customer/service requester. More particularly, customers having problems with attached system devices purchased or otherwise obtained from the supplier or related entity thereof need not subject themselves to the inconvenience and vagaries that a normal service call would entail in terms of time and being interrogated by service personnel with respect to the current status of the functioning of various aspects of the system devices, some of which may be of a highly technical nature. Instead, the present system and method shifts control to the customer as by a single action, e.g. pushing a button or clicking on an icon, the customer can automatically initiate testing of their connected system device and receive a communication regarding its outcome.

As is apparent, if the automated testing resolves the problem(s) associated with the connected system device, there is a significant benefit to the customers/users as they have avoided making traditional service request calls altogether and all of its attendant inconveniences. If the automated testing that is done reveals that further intrusive action is necessary such as by requiring scheduling of a local or in-home service call, the customers still derive the benefit of not having to wait on-line (as by phone or Internet connection, for example) while such testing is performed on the system device to determine the necessity of further servicing. In addition, with communication product type system devices the customer usually must choose whom to call, i.e., between the product or device manufacturer and the service provider. The present invention avoids this dilemma by providing a predetermined routing for the user's service request to initiate the automated testing herein. As far as the service provider is concerned, their servicing operations can also be streamlined significantly in light of the present system and method as no longer do service centers or stations need to be staffed to answer each and every customer call; rather, the service center can now be staffed to contact customers as needed in response to their service request such as by phone or e-mail.

In the preferred form and as will be more particularly described herein, the system includes communication devices that are connected to a hub which affords the devices access to a network of other connected devices and/or information or content providers such as on a wide area network, e.g., the Internet. As is known, interconnected devices are provided with unique network identifiers or addresses enabling connection therewith in accordance with established standard protocols. With the present invention, a customer contact database can be constructed with device addresses associated with customers/users. Upon receiving service requests from users, addresses can be cross-referenced for contact information in the database. This cross-reference database can be a customer billing database, for example. Alternatively, the cross-reference database can be constructed from a product registration card or sheet that the customer fills out at or near the time of purchasing the system device. Oftentimes, consumers do not fill these out or do so only partially, and may be leery of providing a product supplier with their contact information.

However, with the present invention, the devices can be marketed based on the uniqueness of the service program that puts the customer in control, thus also providing customers with an incentive to fill out these registration cards to achieve the full benefits of the product they have purchased. This also provides a potentially valuable user profile or other demographic information that otherwise may not be readily forthcoming via the typical registration process. Where the single registration action required of the user is a phone call, the contact database can be one which is continuously updated with each call as by a touch tone response system which prompts the user to choose a callback method from such options as: (1) the caller i.d. return phone number that can be read back for verification, (2) an alternative phone number provided by the user, or (3) an e-mail address. In this manner, contact information is collected and organized at the time of the service call incident to ensure that an accurate and appropriate callback occurs.

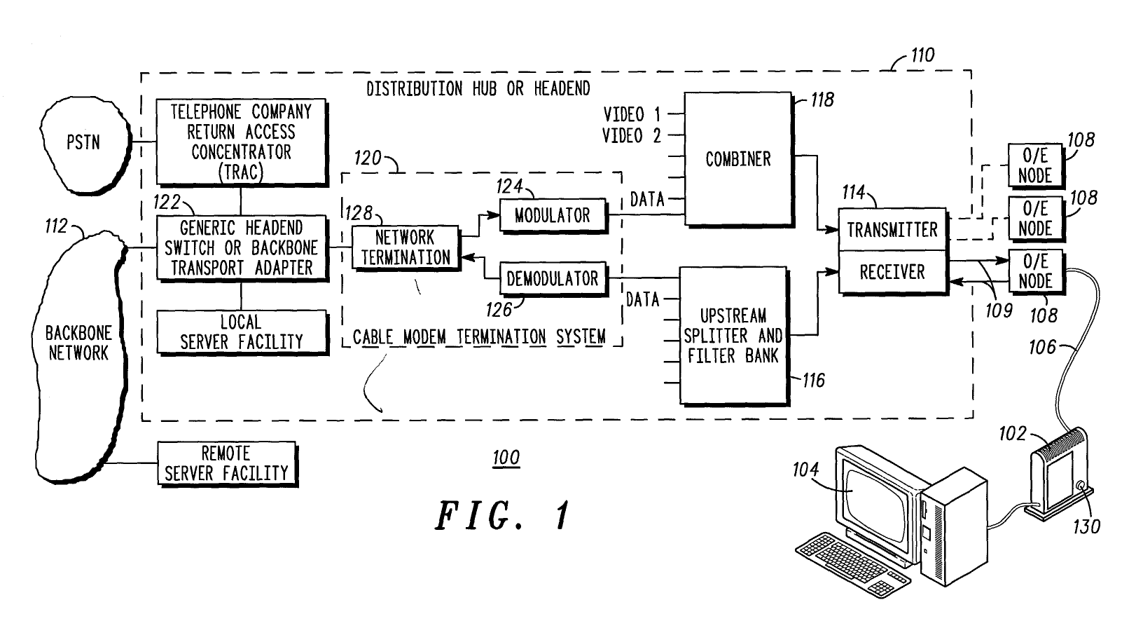

Turning now to the drawings and, more particularly, FIG. 1 shows an example of a self-testable system 100, including a remotely connectable device 102, such as a cable modem testable using self-diagnosis according to the preferred embodiment of the invention. A customer or user is connected to the cable modem 102 through a PC 104. The cable modem 102 is connected with a co-axial cable 106 to an optical/electrical (O/E) interface node 108 which interfaces an electrical signal on the co-axial cable 106 side with an optical signal on an optical fiber 109 side. The O/E node 108 is connected through optical fiber cable 109 to a distribution hub 110, typically known as a headend.

As shown, headend 110 provides an interface between the optical fiber 109 and wide-area network (WAN) 112. A typical headend 110 includes an optical transceiver 114 interfacing the optical signal from fiber 109 to upstream-splitter and filter bank 116 and to the combiner 118. Upstream-splitter and filter bank 116 and combiner 118 are connected to a Cable Modem Terminal System (CMTS) 120. The CMTS 120 is connected through a generic headend switch or backbone transport adapter 122 to the wide-area network 112. CMTS 120 includes a modulator 124 and demodulator 126 which are connected to combiner 118 and to upstream splitter and filter bank 116, respectively. A network termination unit 128 interfaces the modulator 124 and demodulator 126 to the network interface at the generic headend switch or, backbone transporter adapter 122. The preferred cable modem (CM) 102, includes a callback button 130 that may be located physically on the device. Alternatively, the callback button may be a virtual button displayed on the CM subscriber's computer screen as by an icon or the like, or provided on the CM service provider's webpage.

When a customer encounters a problem, the customer activates the call button 130 to initiate system self-test diagnostic by the response system. Pushing the button 130 forces a flag, interrupting the cable modem's normal operation, placing the cable modem in self test mode. The cable modem 102 injects a preselected self-test request code into the upstream data stream that is recognized by the headend 110. Then, the cable modem 102 waits a preselected period for one or more return test pings. If a test ping is not received, the cable modem 102 indicates an error, i.e., that a connection to the service provider is not available and the customer may be directed to call the service provider. The headend 110, upon recognizing the self-test request code initiates self-test. In response the system retrieves subscriber information from a resident subscriber database, initiates the system diagnostics with the remote unit (i.e., the cable modem), prepares a diagnostic summary in response to the diagnostic tests, implements corrective action as appropriate, and notifies the user of any corrective action undertaken. The automated self-testing can be qualitative as by a ping check or more quantitative such as by checking for ingress noise, power levels, error rates or the like.

If the remote device or cable modem 102 cannot connect to the headend 110 and, therefore, to the service provider for diagnostics, then, the service provider must be called manually by the subscriber to initiate corrective action. However, it is expected that, typically, the majority of incidences giving rise to a call are likely to be performance-related calls (where the connection is not in question) that are compatible with the callback feature of the present invention. Furthermore, even if the callback is initiated from a virtual button on a webpage instead of from a button on the device, this is valuable diagnostic information in and of itself. Initiation of the callback indicates that the cable modem user is able to use the cable modem 102 and, instead, is having difficulty accessing the callback site, i.e., the user's problem is service provider reachability, not inability to contact any particular website.

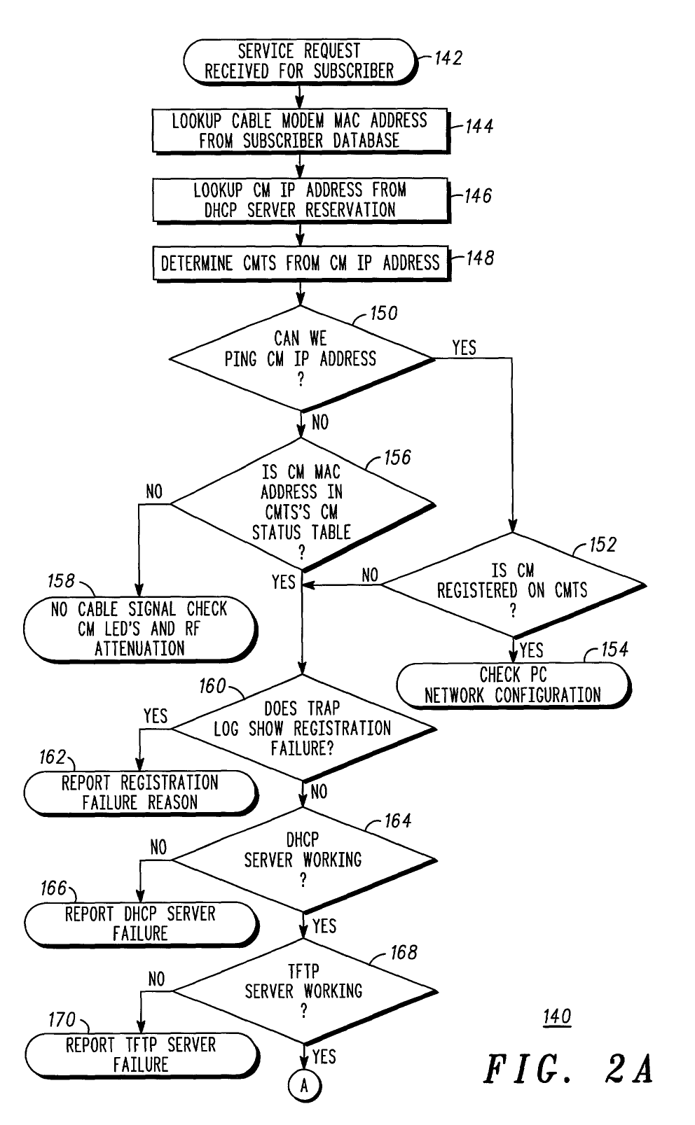

FIGS. 2A and 2B show a flow diagram of a preferred automatic self diagnostic method 140 of the present invention. Referring to FIG. 2A, the auto-diagnostic method 140 is initiated when a user presses the call button which, as noted above, may be located on the cable modem 102 itself, a virtual callback button on the subscriber's computer screen 104 (e.g. in the Windows System Tray) or, a virtual button on the service provider's webpage. Further, the method 140 can be successfully implemented by the placing of a phone call to the service center where the connection between the modem and headend are the problem, as will be described more fully hereafter. The preferred embodiment method 140 of FIG. 2A is described herein with reference to a cable modem 102 with a callback button 130 as described in the example of FIG. 1. However, it is understood that this is for example only and not intended as a limitation. The present invention may be applied to any connectable remote device, such as cellular phones, pagers, land-line modems and cable telephone modems without departing from the invention.

Preferably, users are identified prior to use to enable callback. For cable modem subscribers, this identifying information is available in the customer billing database. User information can be collected when a new subscriber sets up a cable modem account or when the cable company installer does the same. Thus, when a new account is arranged, the customer's preferred telephone number is provided for the callback service. This phone number is sent to the provider as with any online registration, stored in a user database for future reference and, would supersede the phone number of record. When a callback is initiated, the cable modem IP address is retrieved from the requesting callback modem. The IP address is stored in the cable modem 102 and can be garnered from a callback webpage as well. Generally available telemarketing applications, easily adapted for use in accordance with the present invention, are used to: (1) map the CM IP address to the user's callback number, (2) initiate the return call, and then, when the user answers the return call, (3) connect the service representative to the initiating user.

One of the advantages of the present system and method is that it encourages customers to fill out registration cards upon product purchase to reap the service advantage described herein. In other words, for implementing the callback feature provided with the product, the consumer must provide the supplier with contact information on the registration card. This card, which normally may not be returned, will likely be submitted with the contact information to obtain the added value of the present system and method, and thus, the likelihood that other desirable demographic or user profile information requested on the card will also be provided. This additional information can be compiled and has value from a marketing standpoint, as is well understood.

Further, the present invention contemplates the creation of a database that matches the network address of the user's device with their contact information. This network address may be parsed from the service request signal. Thus, the service center can contact the service requester to provide, for instance, confirmation of the service request and, after testing is complete, the test results and information regarding whether further action is necessary. This database can be implemented in a variety of ways in terms of how to collect the information it contains. For example, the information can be gleaned from a customer billing database or the contact information can be taken from the registration process where such information is specifically requested thus superceding that which is in the billing database. Another option is to provide the customer the opportunity to select which means of callback or response is preferred at the time that the service request is placed, such as where the request is initiated by placing a phone call, as will be described hereinafter. This information is then added to the database so that the contact information is updated with each service request.

Continuing in step 144, the service request is received from the subscriber. The service provider interrogates the request, extracting information from the subscriber database and cross referencing the cable modem's machine access code (MAC) address to identify the subscriber. Then, in step 146, the IP address is cross referenced with a Dynamic Host Configuration Protocol (DHCP) Server Reservation to identify the requesting user. In step 148, the CMTS 120 is identified from the cable modem IP address. Thus having identified the requesting cable modem subscriber, connection testing begins in step 150.

At this point, the method 140 contemplates a hierarchy of tests as follows. In step 150, the service provider pings the IP address to determine whether the service provider can communicate with the device at that IP address, i.e., whether there is a physical connection. If the cable modem IP address is pingable, indicating that the cable modem 102 is connected to the headend, then in step 152, a determination is made whether or not the particular cable modem 102 is registered on the CMTS 120, which should have occurred upon initialization of the cable modem. If the cable modem 102 is found to be registered, then in step 154, the networking configuration for the requesting user is checked and performance and diagnostic self-tests are run on the cable modem connection and on the cable modem itself. Step 154 can include tests that ping small and large (e.g. 1500 byte) packets, since the system may respond to small packet pings but not large ones. A frequent symptom of poor cable upstream RF connection is that small packets go through but large ones do not. The automated diagnostic process 140 can recognize this and automatically determine that a service call is required which can be communicated to the user/service requester or the web site and/or the voice response unit at the service center, as the case may warrant.

However, if in step 150 the cable modem IP address does not respond to the ping, then in step 156, a check is made to determine whether the cable modem's MAC address is logged in a cable modem status table maintained by the CMTS 120. Optionally, while the modem is waiting for the ping, local diagnostics may be run on the cable modem and its connection to the user's computer. This local diagnostics may include, for example, cable modem power on self test (POST) routines and/or software diagnostics already in place for testing the cable modem connection. In step 156, if the cable modem MAC address is not found in the CMTS's CM status table, which contains ranged but not yet registered modems, then, in step 158, the customer is directed to check the cable modem displays, i.e., light emitting diodes (LEDs) and radio frequency (RF) attenuation level. However, if in step 156 the cable modem's MAC address is logged in the status table, or, in step 152 the cable modem is found to not be registered in the CMTS, continuing to step 160, the trap log is checked for a registration failure. If a registration failure is found, it is reported in step 162 with a reason for failure.

Otherwise, continuing in step 164, the DHCP server is checked to determine if it is up and running. If the DHCP server is not functional, then in step 166, that failure is reported. If the DHCP server is working, continuing to step 168, the Trivial File Transfer Protocol (TFTP) server is checked to determine if it is functioning. If the TFTP server is not functioning, in step 170, that failure is reported. However, if the TFTP server is functioning, then, in step 172, as shown in FIG. 2B, the DHCP log of the modem's DHCP Discover is checked for an entry corresponding to the CM 102. If no entry is found in the DHCP log for the DHCP Discover, then, in step 174, the CMTS log of the DHCP Discover is checked for an entry corresponding to the CM 102. If there is no entry in the CMTS log either, then in step 176, an indication is made that there is no DHCP connection to the cable modem 102. Otherwise, in step 178, an indication is made that the DHCP helper address logged in the CMTS is invalid. However, if a proper entry is found in the DHCP log in step 172, then in step 180, the TFTP server is checked for a logged request. If no request is found, then, in step 182, the CMTS to TFTP IP routing is checked. Otherwise, in step 184, the CM config file is checked.

As is apparent by way of the present system, once the source of the problem is identified, corrective action can then be taken with the source or sources of the problems having been identified with only a single action required by the requestor. Thus, the customer avoids having to wait on the phone and respond to potentially numerous queries regarding the system and its status and functional ability.

Accordingly, unlike currently well known customer service approaches, the preferred embodiment of the present invention places the user/customer in control of the service call. The customer may receive a response without ever being tied to the phone, waiting for an answer or waiting for diagnostic work to progress. Preferably, the callback button 130, would be place very prominently the cable modem 102 to provide the customer with a feeling of security and a general awareness of the callback button 130. Thus, the only skill required in the customer using the present invention is knowing how to press the callback button 130 to initiate self diagnostics.

Advantageously, diagnostic checks are run automatically at the customer's request. Further, when a request for diagnostics is received, initially, a service representative can analyze the test results for potentially well understood problems that have quick easy answers. Once the analysis is done, the service representative can respond to the request for service by either sending/leaving a message or, speaking directly to a customer and explaining what action has been taken or must be taken. So, for example, in a major service outage, when a large number of customers are making nearly identical callback requests, a single simultaneous response to all of the customers' request may be handled expeditiously by the service provider replying to all callback buttons at once. Thus, the service provider may respond either with a common e-mail response (if appropriate) to all of the requests or, by replying individually in an orderly fashion. Either response would occur without subjecting individual customers to the frustrating experience of a constant busy signal, being placed on hold and waiting for long periods to speak to customer service representative at the service center helpdesk. In addition, the service center would not be inundated with what, potentially, could be hundreds of phone calls, all related to the same or similar problem. Further, and as mentioned, the service center can provide a focused response and en mass, rather than having to respond individually with the same report to a large number of customers that are experiencing the same problem.

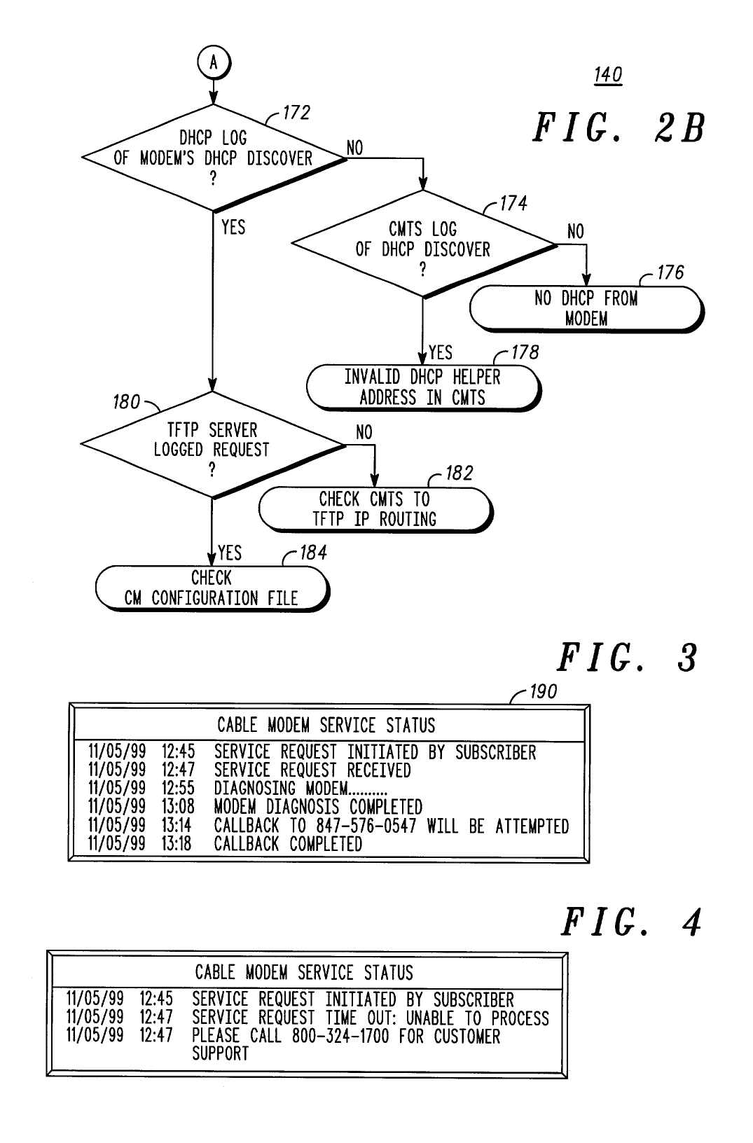

FIG. 3 is an example of a cable modem service call status window 190 which may be provided to inform the requesting user. Typical modem access software, normally included on a personal computer (PC), can be modified to provide the status window, indicating: if contact was successfully made to the service provider, i.e., at the headend 110; if system diagnostic data has been collected; and, if the system has attempted a callback.

FIG. 4 is an example of a window for directing the customer to contact the service provider during a complete cable modem communications failure, e.g., when the return ping is not received. In the case of a complete headend contact failure, the display might direct that the customer to manually contact (call) the service provider.

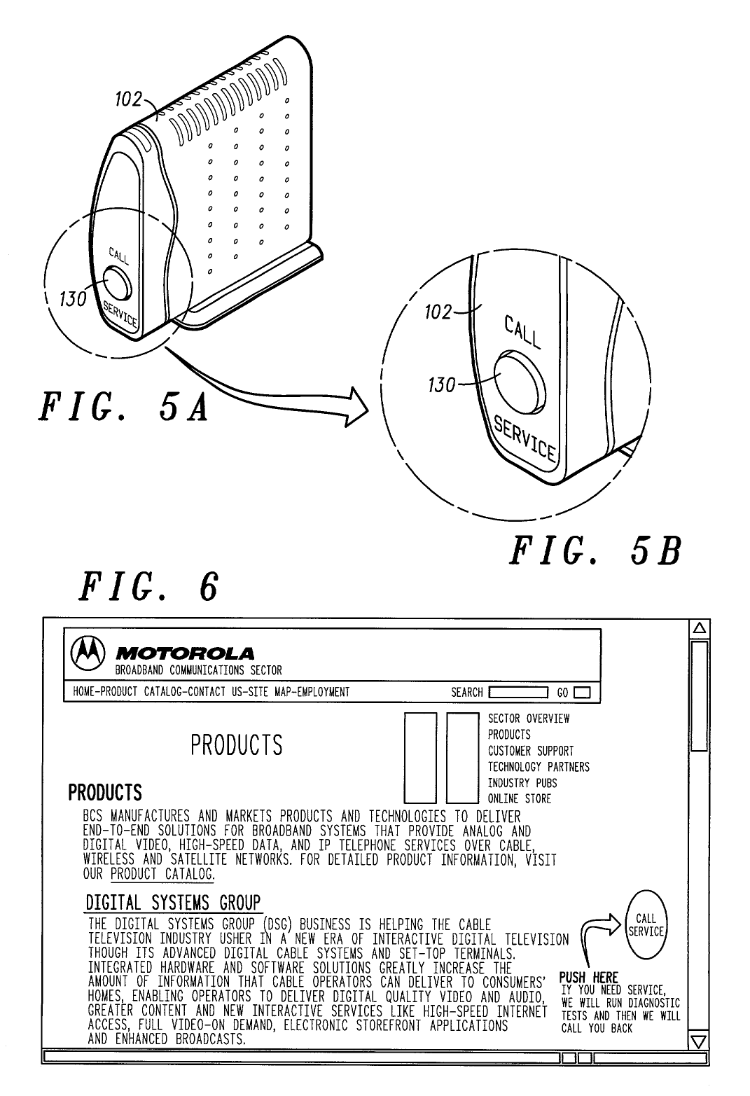

FIGS. 5A and 5B show an example of a cable modem 102 with a callback button 130 prominently located according to a first preferred embodiment. FIG. 5B is an expanded view of area B in FIG. 5A. When a user encounters a service interruption or other performance issues cause concern, the user simply presses the callback button 130. In response, the cable modem sends an alert to the headend administration system. The alert indicates that the user is encountering difficulties or has service questions. The administration system then would direct a support technician (or, alternatively, an automated test system may be diverted) to run the appropriate diagnostic programs on the system such as shown in FIGS. 2A-2B. After analyzing the results, the customer is called at the listed emergency number found in the customer database.

FIG. 6 is an illustration of a website callback button in another embodiment wherein the customer selects the website, and clicks on the website button to initiate a callback from the website. Thus, in this embodiment, upon selecting the “call me” button on the cable service provider's webpage, the process of FIGS. 2A-2B is initiated. The software, executed by the webpage button selection determines the IP address of the initiator and, extracts the associated subscriber information from the aforedescribed database prior to initiating a service response. The webpage alternatively can request that information from the user, as well as any other information that may be helpful in running the automated testing herein, and diagnosing the problems being encountered. Unlike the preferred embodiment, this second embodiment requires no new or special equipment. This embodiment cannot be used, however, when the problem is in the cable modem 102, headend 110 or therebetween, unless the customer has an alternate Internet connection, e.g., a dial-up modem and connection.

In yet another embodiment, the user initiates a callback request through a telephone call. In this embodiment, the customer dials in to the service provider, connects to the customer database, enters a customer identification and the diagnostic tests are run on the cable system connection, as shown in FIGS. 2A-2B. User notification preferences can be collected either at the time of registration or at the time of the service call incident, as previously described. In the telephone call service instruction request form, the notification information can be requested through a touch-tone response system which prompts the caller to choose a call back option, such as: (1) caller i.d. return call number, which could be read back to the requester for verification, (2) an alternative phone number, or (3) an e-mail address.

After running the diagnostics tests, the user receives a communication from the service organization, or, optionally, just waits online for an automated response. So, for example, a voice response system coupled with a caller ID function, may be used to initiate the service request. The response system consults with the user database to map the caller ID number to the cable modem IP address. Thus, in this embodiment, the user is presented with a selection of options, which include initiating a network test of the cable modem. After running the tests, a voice response system may prompt a user callback response or, if the user remains on the line, the system responds to the waiting user with test results and system status.

Accordingly, when a problem is found the voice response system may respond with, for example: “We are unable to contact your modem. Please press 1 for additional troubleshooting information, or press 2 to speak with the next available service technician.” If, however, the above-described tests indicate that the connection is good, then, the automatic self diagnostic system of the present invention would proceed with additional tests in step 154, for example, pinging large packets.

As previously discussed, a frequent symptom of poor cable upstream RF connections is that small packets pass upstream between nodes but, large packets do not. The automatic diagnostic self-test of the present invention may include such additional tests to recognize this problem and, to automatically determine when a service call is required as a result of failing this test. Again, the response from the voice response system may be something to the effect that: “We have detected problems with your cable connection. Please hold for the next available representative to schedule a maintenance technician visit with you.” Clearly, for the occurrence of such a problem in the cable modem or in the cable modem connection, sending e-mail is not a practical response. However, if as a result of the self diagnostic tests, it is determined that network traffic, for example, is the problem, e-mail would be an appropriate and preferred means of communicating diagnostic results to the user.

While the invention has been described in terms of preferred embodiments, those skilled in the art will recognize that the invention can be practiced with modification within the spirit and scope of the appended claims.

We claim:

1. A system of remotely distributed devices connectable together over a network, said system comprising:
a distribution hub;
one or more connectable devices connected to said distribution hub;
a test initiator accessible from at least one of said connected remotely connectable devices; and
a testing unit that tests the operation of the one remote device in response to initiation from said test initiation unit.

2. A system as in claim 1, the testing unit comprising:
means for identifying one of said one or more remotely connected devices as being associated with an initiating connection test initiator; and
means for pinging said identified one remotely connected device.

3. A system as in claim 2, wherein the testing unit further comprises:
means for determining whether said identified one remotely connected device has previously registered with said network.

4. A system as in claim 1, wherein at least one of said remotely connected devices, is a cable modem connected to a distribution hub.

5. A system where as in claim 4, said test initiator includes a button on said cable modem for being actuated to initiate a test of said cable modem's connection to said distribution hub and to said network.

6. A system as in claim 4, wherein said test initiator is a virtual button on a website.

7. A system as in claim 4, wherein said test initiator is a virtual button on a computer display.

8. A system as in claim 1 further comprising:
an automatic response system providing initiating users with connection test results.

9. A system as in claim 8, wherein the automatic response system comprises a voice response system dialing initiating users and providing a vocal report of test results.

10. A system as in claim 8, wherein the automatic response system comprises an e-mail server automatically sending e-mail test reports to initiating users.

11. A method of automatically testing and diagnosing problems associated with each of a plurality of remotely connected devices on a network of said remotely connected devices, each of said remotely connected devices being uniquely identifiable, at least one of said remotely connected devices being capable of initiating a service request, said method comprising the steps of:
a) identifying one remotely connected device as being associated with a service check request, a requesting user making said service check request;
b) pinging said identified remotely connected device;
c) examining system logs to determine if an error is indicated for said one remotely connected device; and
d) reporting service check results to said requesting user using said one remotely connected device.

12. A method as in claim 11, wherein said identified one remotely connected device is a cable modem and, the step (a) of identifying the one remotely connected device comprises the steps of:
i) identifying a cable modem machine access code (MAC) address from a subscriber database;
ii) identifying a cable modem Internet protocol (IP) address from a Dynamic Host Configuration Protocol (DHCP) server reservation; and
iii) determining a Cable Modem Terminal System (CMTS) from the said cable modem IP address.

13. A method as in claim 12 wherein, if it is determined in step (b) that the cable modem associated with the requesting user is pingable, then, a determination is made whether the cable modem is registered on the CMTS.

14. A method as in claim 13, wherein if it is determined that the cable modem is registered on the CMTS, then, the requesting user's personal computer (PC) networking configuration is checked.

15. A method as in claim 11 wherein, if in step (b) it is determined that the requesting user's cable modem is not pingable, the method further comprising the step of:
b1) determining if the CMTS contains an entry corresponding to the requesting user's cable modem MAC address in a status table.

16. A method as in claim 15 wherein, if the cable modem MAC address is not found in the status table, the requesting user is directed to physically check the cable modem for an indication of connection to the network.

17. A method as in claim 11, wherein the step (c) of examining logs to determine if an error is indicated comprises the steps of:
i) checking a trap log for registration failure;
ii) checking said DHCP Server determine if it is functioning;
iii) checking said TFTP Server to determine if it is working; and
iv) checking for the cable modem's DHCP Discover in the DHCP log.

18. A method as in claim 17 wherein, if the step (c) (i), if the trap log shows a registration failure, said registration failure is reported in step (d).

19. A method as in claim 17 wherein, if the step (c) ( ii) it is determined that the DHCP Server is not working, a DHCP Server failure is reported in step (d).

20. A method as in claim 17 wherein, if the in step (c) (iii) the TFTP Server is not working, then, a TFTP Server failure is reported in step (d).

21. A method as in claim 17 wherein, if in step (c) (iv) the cable modem's DHCP Discover is not found, then, the method further comprises the steps of:
checking the CMTS log for a DHCP Discover,
reporting an invalid DHCP helper address condition when the DHCP Discover is found in the CMTS log, and otherwise
indicating that the cable modem did not provide a DHCP Discover.

22. A method as in claim 20 wherein, if in step (c) (iv) the cable modem's DHCP Discover is found in the DHCP log, the method further comprising the steps of:
checking the TFTP Server for a logged request, and
checking the cable modem config file when a logged request is found in TFTP Server and, otherwise
checking the CMTS to TFTP IP routing.

23. A servicing system for testing networked devices, the servicing system comprising:
a servicing station remote from devices to be tested with the devices being linked to the station;
predetermined diagnostic testing implemented on the devices;
a testing initiation signal generated by a user for having the predetermined diagnostic testing automatically performed on one of the devices associated with the user without requiring the user to be subject to interrogations by personnel at the servicing station; and
a predetermined responsive communication mode through which the user receives information regarding results of the automated testing from the service station in a manner preselected by the user.

24. The servicing system of claim 23 wherein the devices are cable modems and the predetermined diagnostic testing includes software of the modems configured to undertake the testing.

25. The servicing system of claim 23 including a contact database maintained by the servicing station for correlating user contact information and an identifier for the device associated with the user.

26. The servicing system of claim 25 wherein the devices are cable modems and the identifier is an IP address.

27. The servicing system of claim 23 wherein the testing initiation signal is a flag, said flag causing said one device to send a self-test request code to said servicing station.

28. The servicing system of claim 27 wherein the devices are cable modems and said cable modems entering self-test mode responsive to said flag.

29. The servicing system of claim 28 wherein responsive to said self test code from one of said cable modems, said servicing station pings said one cable modem with multiple packet sizes.

30. The servicing system of claim 23 wherein the predetermined diagnostic testing is a hierarchy of tests selected based on predetermined problems that have a high occurrence probability when diagnostic testing is deemed necessary.
